(19) United States
(12) Patent Application Publication
(10) Pub. No.: US 2026/0182101 A1
(43) Pub. Date: Jun. 25, 2026

(54) LIGHT EMITTING DIODE AND MANUFACTURING METHOD THEREOF

(71) Applicant: Taiwan-Asia Semiconductor Corporation, Hsinchu City (TW)

(72) Inventor: Jun-Ying Lin, Hsinchu City (TW)

(21) Appl. No.: 19/235,753

(22) Filed: Jun. 12, 2025

(30) Foreign Application Priority Data
Dec. 19, 2024 (TW) 113149541

(51) Int. Cl. H10H 20/841; H10H 20/01; H10H 20/833

(52) U.S. Cl. CPC H10H 20/841; H10H 20/017; H10H 20/032; H10H 20/034; H10H 20/833

(57) ABSTRACT

A light-emitting diode (LED) and its manufacturing method are provided. The LED comprises a substrate, an epitaxial composite layer, a light-restricting layer, and a transparent conductive layer. The epitaxial composite layer includes a first compound semiconductor layer, a light-emitting layer, and a second compound semiconductor layer, where the first compound semiconductor layer is sandwiched between the substrate and the light-emitting layer. The light-restricting layer, having a light-restricting opening, is disposed between the light-emitting layer and the second compound semiconductor layer. The transparent conductive layer is disposed on the epitaxial composite layer. The light emitted by the light-emitting layer is restricted to pass through the light-restricting opening of the light-restricting layer before being emitted externally via the transparent conductive layer.

### CROSS-REFERENCES TO RELATED APPLICATIONS

This application claims the benefit of priority to Taiwanese Patent Application No. 113149541 filed on Dec. 19, 2024, which is hereby incorporated by reference in its entirety.

### BACKGROUND OF THE INVENTION

### Field of the Invention

This invention relates to a light-emitting diode and a manufacturing method thereof, and in particular to a light-emitting diode capable of serving as a point light source and a manufacturing method thereof.

### Descriptions of the Related Art

A light-emitting diode (LED) offers advantages such as high brightness, compact size, low power consumption, and long lifespan. As a point light source, an LED exhibits excellent directionality, small size, and concentrated energy, making it widely used in various fields. For example, in optical applications, LEDs serve as point light sources in optical sensors for devices such as blood oxygen monitors and distance measurement systems. In fiber optic communications, LEDs can be used at the transmitting end to provide collimated light sources, facilitating signal transmission. Additionally, in applications such as rotary encoders, an LED can be combined with a photosensor, where light emitted from the point light source passes through a slotted disk to illuminate the sensor, converting rotational position, speed, and other information into digital signals for subsequent digital signal processing applications.

For the conversion of optoelectronic signals in signal transmission devices, particular emphasis is placed on the ability of point light sources to provide high precision and collimation. However, conventional LED structures suffer from drawbacks such as insufficient point light source intensity and poor directionality. Therefore, there is an urgent need in the industry for an innovative LED structure and manufacturing method to enhance the intensity of point light source products, thereby increasing design flexibility for downstream module applications.

### SUMMARY OF THE INVENTION

The main objective of this invention is to provide a light-emitting diode and a manufacturing method thereof. The disclosed LED structure enhances the emission intensity of a point light source, particularly in fields requiring high precision, high brightness, and long lifespan, thereby increasing design flexibility and market competitiveness for downstream application products.

To achieve the above objective, this invention provides a light-emitting diode comprising a substrate, an epitaxial composite layer, a light-restricting layer, and a transparent conductive layer. The epitaxial composite layer includes a first compound semiconductor layer, a light-emitting layer, and a second compound semiconductor layer, with the first compound semiconductor layer sandwiched between the substrate and the light-emitting layer. The light-restricting layer, having a light-restricting opening, is disposed between the light-emitting layer and the second compound semiconductor layer. The transparent conductive layer is disposed on the epitaxial composite layer. The light emitted by the light-emitting layer is restricted to pass through the light-restricting opening of the light-restricting layer before being emitted externally via the transparent conductive layer.

In one embodiment of the light-emitting diode of this invention, the light-restricting opening has a minimum opening inner diameter, which has an inverse variable relationship with the emission wavelength band of the light-emitting layer.

In one embodiment of the light-emitting diode of this invention, when the emission wavelength band of the light-emitting layer varies from 620 nanometers (nm) to 940 nanometers (nm), the minimum opening inner diameter varies from 45 micrometers (μm) to 30 micrometers (μm).

In one embodiment of the light-emitting diode of this invention, the light-restricting opening has a maximum opening inner diameter of 60 micrometers (μm).

In one embodiment of the light-emitting diode of this invention, the light-restricting layer is an oxide layer.

In one embodiment of the light-emitting diode of this invention, the transparent conductive layer has a minimum thickness, which has a positive variable relationship with the emission wavelength band of the light-emitting layer.

In one embodiment of the light-emitting diode of this invention, when the emission wavelength band of the light-emitting layer varies from 620 nanometers (nm) to 940 nanometers (nm), the minimum thickness varies from 2400 angstroms (Å) to 4400 angstroms (Å).

In one embodiment of the light-emitting diode of this invention, the material of the transparent conductive layer is selected from the group consisting of indium tin oxide (ITO), indium zinc oxide (IZO), zinc tin oxide (ZTO), aluminum-doped zinc oxide (AZO), gallium-doped zinc oxide (GZO), fluorine-doped tin oxide (FTO), and combinations thereof.

In one embodiment of the light-emitting diode of this invention, the first compound semiconductor layer is a first conductivity-type aluminum gallium arsenide (AlGaAs) layer, and the second compound semiconductor layer is a second conductivity-type aluminum gallium arsenide layer.

In one embodiment of the light-emitting diode of this invention, the light-emitting diode further comprises a gallium phosphide (GaP) layer sandwiched between the second conductivity-type aluminum gallium arsenide layer and the transparent conductive layer, and forming an ohmic contact with the transparent conductive layer.

In one embodiment of the light-emitting diode of this invention, the light-emitting diode further comprises a reflective layer disposed between the substrate and the first compound semiconductor layer to reflect light emitted by the light-emitting layer through the light-restricting opening of the light-restricting layer before being emitted externally via the transparent conductive layer.

In one embodiment of the light-emitting diode of this invention, the reflective layer is a distributed Bragg reflector (DBR).

To achieve the above objective, this invention provides a manufacturing method of a light-emitting diode, comprising the following steps. First, provide an epitaxial composite layer disposed on a substrate, wherein the epitaxial composite layer includes a first compound semiconductor layer, a light-emitting layer, and a second compound semiconductor layer, with the first compound semiconductor layer sandwiched between the substrate and the light-emitting layer. Next, provide a light-restricting layer disposed between the light-emitting layer and the second compound semiconductor layer, wherein the light-restricting layer has a light-restricting opening. Finally, provide a transparent conductive layer disposed on the epitaxial composite layer, wherein the light emitted by the light-emitting layer is restricted to pass through the light-restricting opening of the light-restricting layer before being emitted externally via the transparent conductive layer.

In one embodiment of the manufacturing method of the light-emitting diode of this invention, the step of providing a light-restricting layer is a step of providing a light-restricting layer with a light-restricting opening having a minimum opening inner diameter, wherein the minimum opening inner diameter has an inverse variable relationship with the emission wavelength band of the light-emitting layer, and when the emission wavelength band of the light-emitting layer varies from 620 nanometers (nm) to 940 nanometers (nm), the minimum opening inner diameter varies from 45 micrometers (μm) to 30 micrometers (μm).

In one embodiment of the manufacturing method of the light-emitting diode of this invention, the step of providing a light-restricting layer is a step of providing a light-restricting layer with a light-restricting opening having a maximum opening inner diameter of 60 micrometers (μm).

In one embodiment of the manufacturing method of the light-emitting diode of this invention, the method further comprises a mesa etching process to etch and remove a portion of the epitaxial composite layer, exposing a sidewall of the epitaxial composite layer.

In one embodiment of the manufacturing method of the light-emitting diode of this invention, the step of providing a light-restricting layer is a step of performing a wet oxidation process, allowing oxygen and water to enter the epitaxial composite layer through the exposed sidewall of the epitaxial composite layer to form an oxide layer between the light-emitting layer and the second compound semiconductor layer.

In one embodiment of the manufacturing method of the light-emitting diode of this invention, the step of providing a transparent conductive layer is a step of providing a transparent conductive layer with a minimum thickness, wherein the minimum thickness has a positive variable relationship with the emission wavelength band of the light-emitting layer, and when the emission wavelength band of the light-emitting layer varies from 620 nanometers (nm) to 940 nanometers (nm), the minimum thickness varies from 2400 angstroms (Å) to 4400 angstroms (Å).

In one embodiment of the manufacturing method of the light-emitting diode of this invention, the material of the transparent conductive layer is selected from the group consisting of indium tin oxide (ITO), indium zinc oxide (IZO), zinc tin oxide (ZTO), aluminum-doped zinc oxide (AZO), gallium-doped zinc oxide (GZO), fluorine-doped tin oxide (FTO), and combinations thereof.

In one embodiment of the manufacturing method of the light-emitting diode of this invention, the first compound semiconductor layer is a first conductivity-type aluminum gallium arsenide (AlGaAs) layer, and the second compound semiconductor layer is a second conductivity-type aluminum gallium arsenide layer.

In one embodiment of the manufacturing method of the light-emitting diode of this invention, the method further comprises a step of providing a gallium phosphide (GaP) layer, wherein the gallium phosphide layer is sandwiched between the second conductivity-type aluminum gallium arsenide layer and the transparent conductive layer, and forming an ohmic contact with the transparent conductive layer.

In one embodiment of the manufacturing method of the light-emitting diode of this invention, the method further comprises a step of providing a reflective layer disposed between the substrate and the first compound semiconductor layer to reflect light emitted by the light-emitting layer through the light-restricting opening of the light-restricting layer before being emitted externally via the transparent conductive layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A to FIG. 1N illustrate schematic diagrams of manufacturing a light-emitting diode in one embodiment of this invention; and

FIG. 2 is a schematic diagram of the process steps for manufacturing a light-emitting diode in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

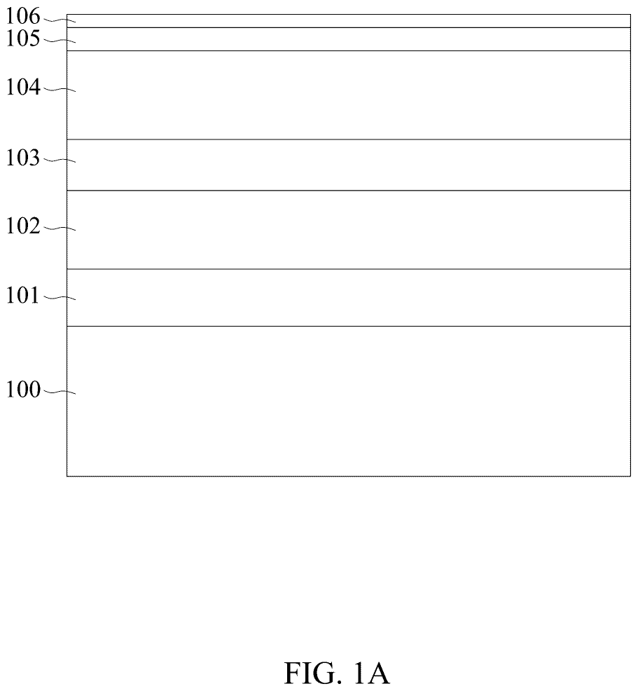

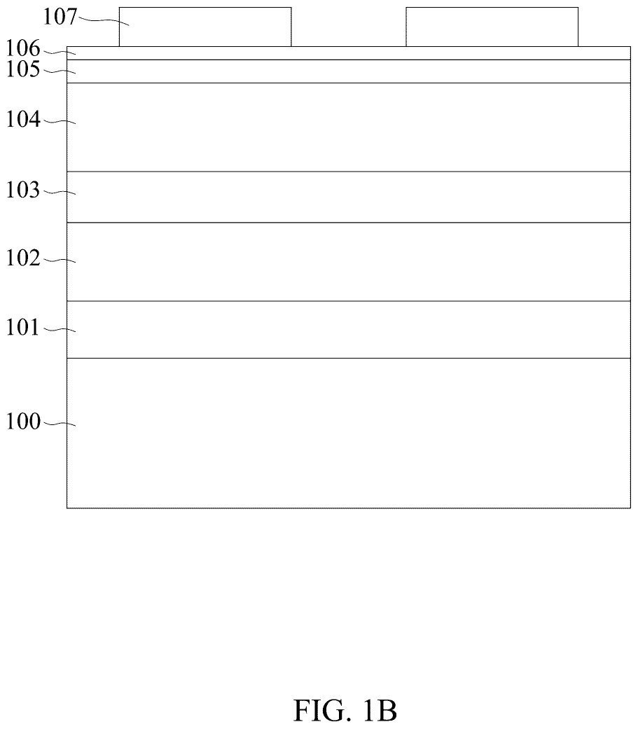

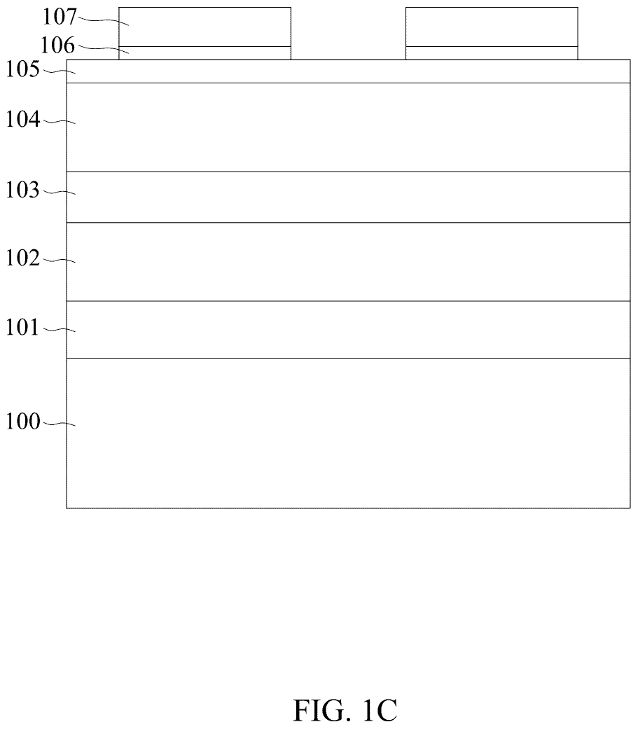

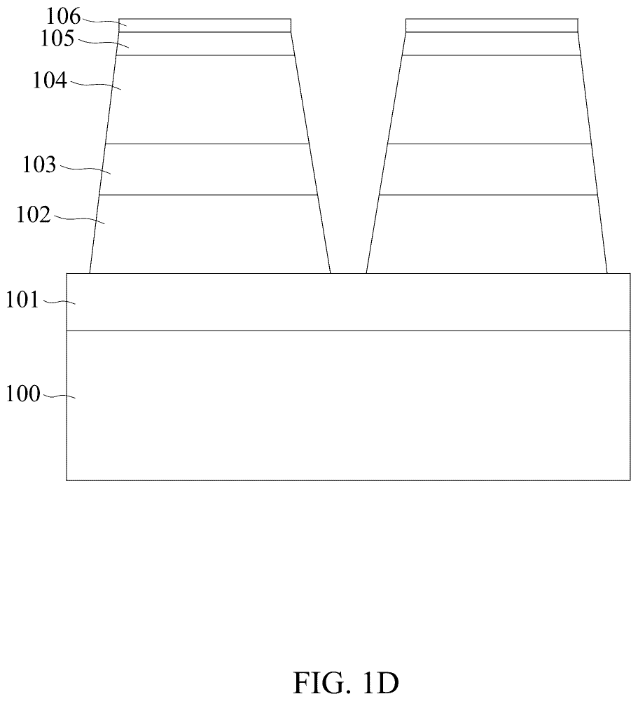

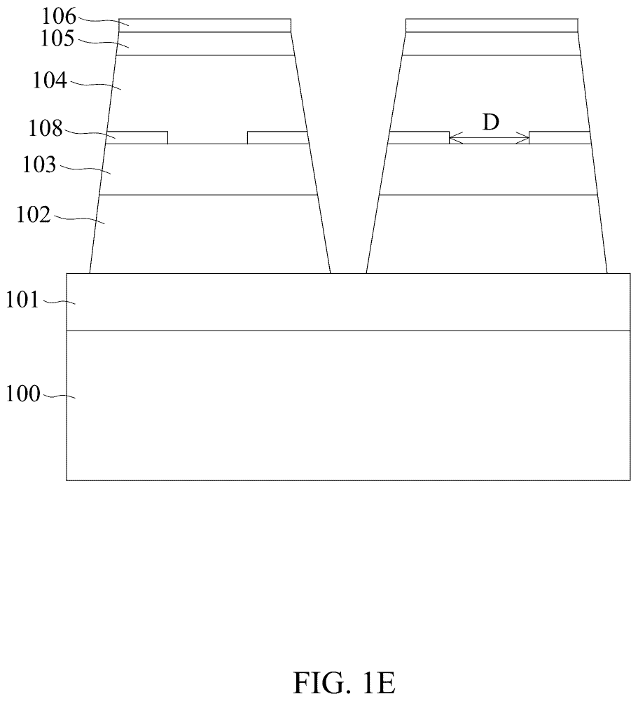

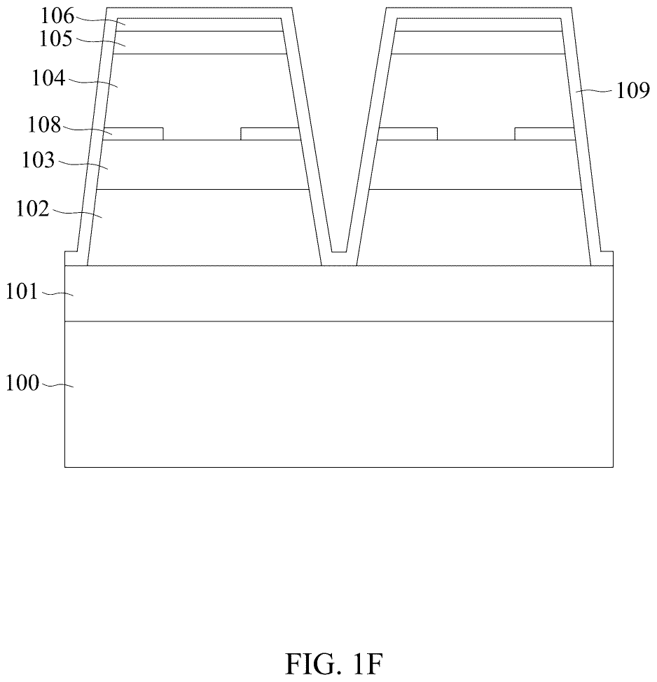

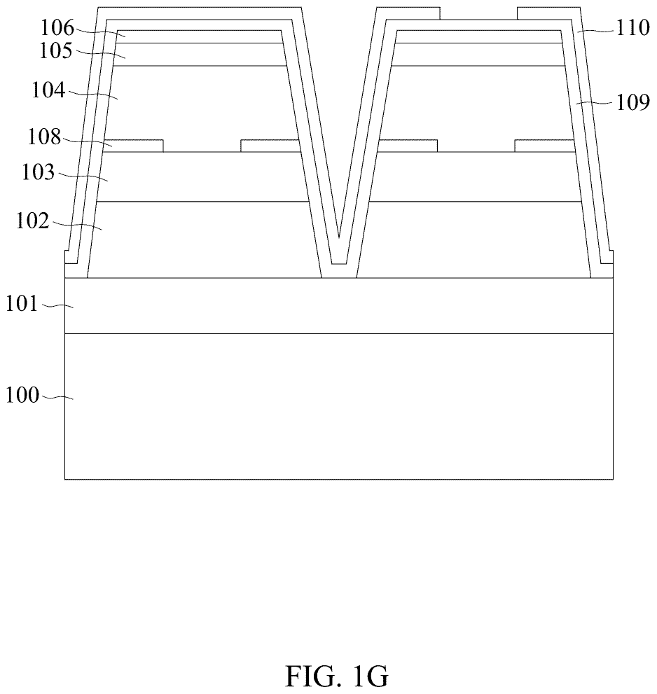

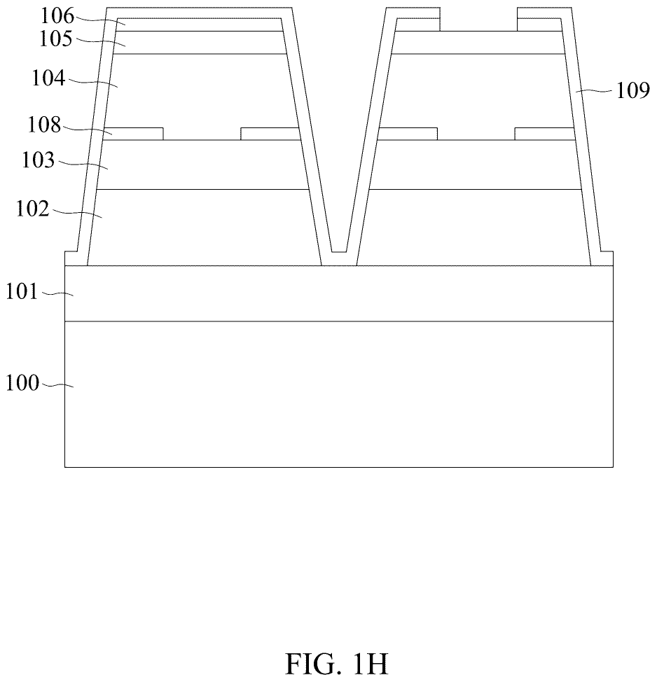

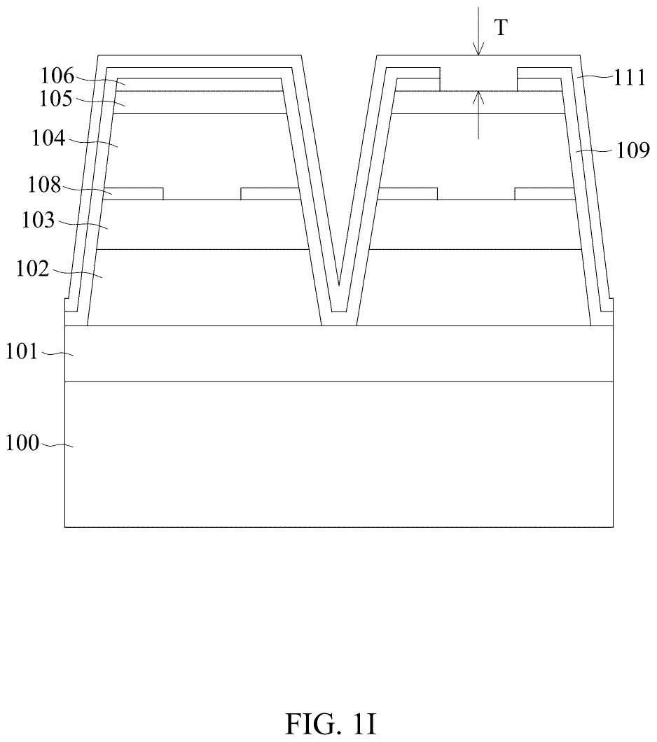

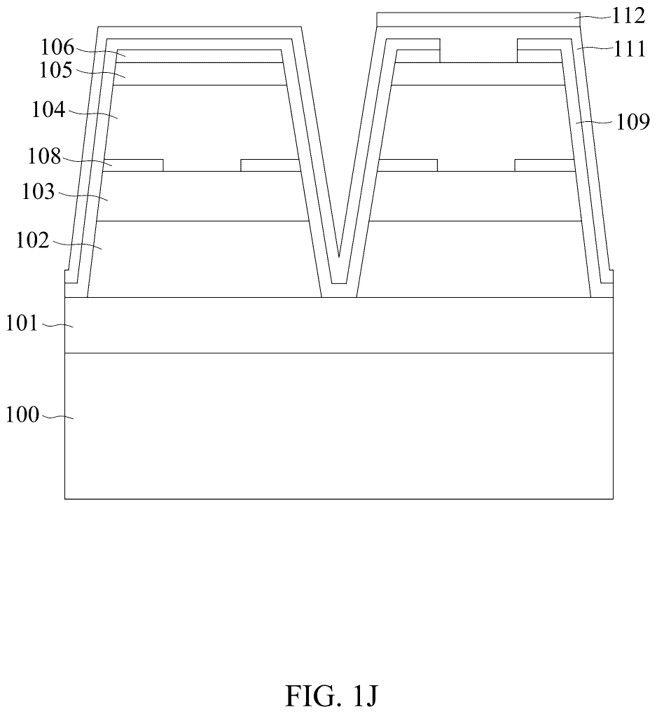

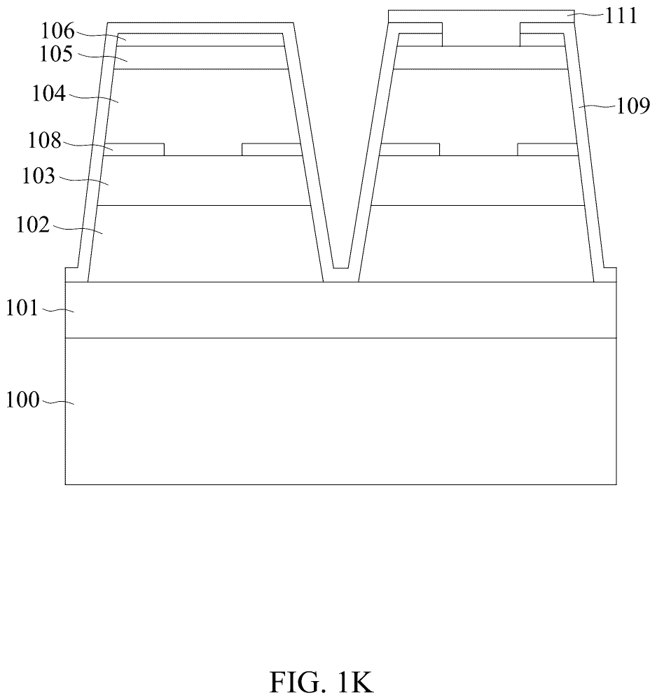

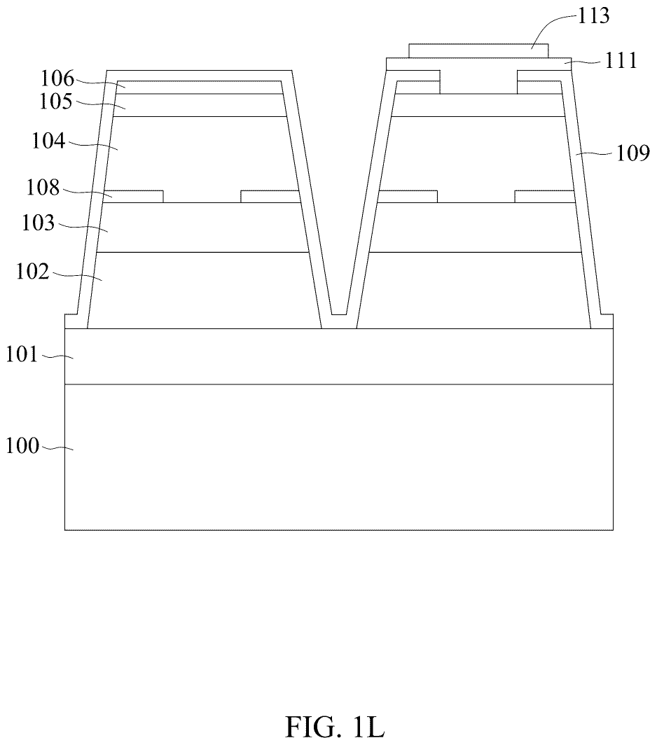

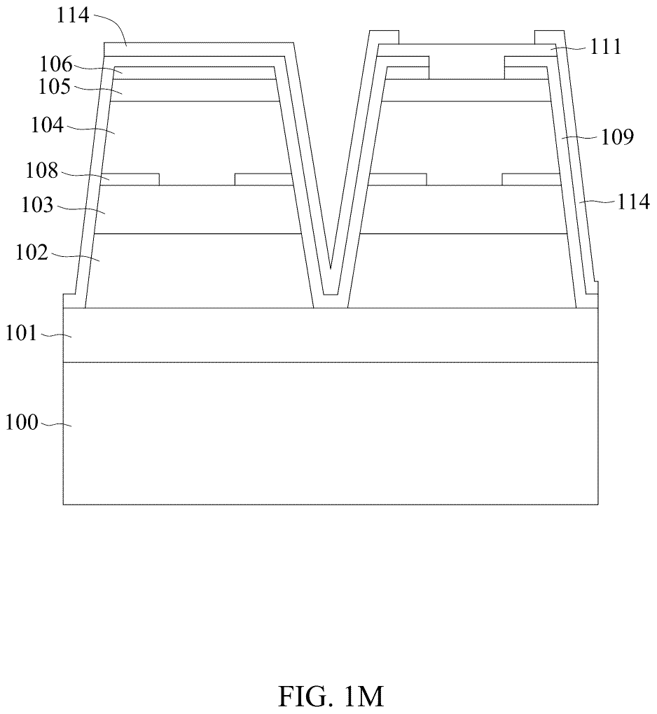

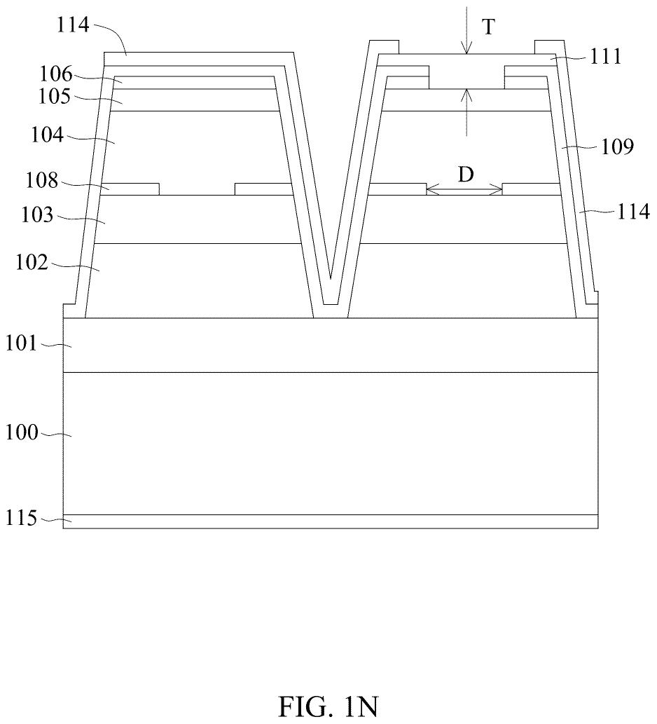

This invention discloses a light-emitting diode and a manufacturing method thereof. Please refer to FIG. 1A, which illustrates an epitaxial growth substrate 100 having a reflective layer 101 and an epitaxial composite layer. Specifically, the epitaxial growth substrate 100 is a gallium arsenide (GaAs) substrate, but is not limited thereto. It should be noted that, since gallium arsenide has a direct bandgap of approximately 1.42 electron volts (eV), corresponding to a wavelength of about 870 nanometers (nm), for light in the red and partial infrared wavelength bands, the photon energy is sufficient to excite electrons from the valence band to the conduction band, causing the gallium arsenide substrate to absorb light in this wavelength range. Therefore, in the embodiment of this invention, a reflective layer 101 is specifically disposed between the epitaxial growth substrate 100 and the epitaxial composite layer to reflect light emitted by the light-emitting layer in the epitaxial composite layer for preventing light absorption by the substrate and reducing emission efficiency. Specifically, the reflective layer 101 may be, for example, but not limited to, a distributed Bragg reflector (DBR).

Next, the epitaxial composite layer is grown using techniques such as Metal Organic Chemical Vapor Deposition (MOCVD) or Molecular Beam Epitaxy (MBE). The epitaxial composite layer comprises a first compound semiconductor layer 102, a light-emitting layer 103, and a second compound semiconductor layer 104. The light-emitting layer 103 is formed by a multiple quantum well (MQW) structure made of ternary compound semiconductors such as indium gallium arsenide (InGaAs) or aluminum gallium arsenide (AlGaAs), or quaternary compound semiconductors such as aluminum indium gallium arsenide (AlInGaAs) or indium gallium arsenide phosphide (InGaAsP), and is sandwiched between the first compound semiconductor layer 102 and the second compound semiconductor layer 104, with the first compound semiconductor layer 102 disposed between the reflective layer 101 and the light-emitting layer 103. In this embodiment, the emission wavelength band of the multiple quantum well may range from 660 to 1000 nanometers (nm), but is not limited thereto. Specifically, the first compound semiconductor layer 102 is a first conductivity-type (N-type) aluminum gallium arsenide (AlGaAs) epitaxial layer, and the second compound semiconductor layer 104 is a second conductivity-type (P-type) aluminum gallium arsenide (AlGaAs) epitaxial layer. It should be noted that the materials described in the above embodiment are merely exemplary, and the present invention is not limited thereto. In practical applications, the materials and their compositions may be adjusted based on the emission wavelength.

As shown in FIG. 1A, a compound semiconductor layer is further epitaxially grown on the epitaxial composite layer. In a specific embodiment, this compound semiconductor layer is a P-type ohmic contact layer 105, such as, but not limited to, a carbon-doped gallium phosphide (GaP) epitaxial layer, with a preferred thickness of 100 to 1000 angstroms (Å). In particular, the doping concentration of this carbon-doped gallium phosphide epitaxial layer is between 1018 and 10²⁰ cm⁻³, which helps reduce contact resistance to form an ohmic contact with the subsequent transparent conductive layer interface. Subsequently, a silicon nitride layer 106 is deposited on the P-type ohmic contact layer 105 for use in subsequent mesa etching.

Please refer to FIG. 1B, where a patterned photoresist layer 107 is formed on the silicon nitride layer 106. This patterned photoresist layer 107 is used for subsequent mesa structure etching of the light-emitting diode. As shown in FIG. 1C, reactive ion etching (RIE) is performed using the patterned photoresist layer 107 to transfer the mask pattern onto the silicon nitride layer 106, followed by inductively coupled plasma (ICP) dry etching to form a mesa structure with a depth of approximately 6 to 10 micrometers (μm), preferably 8 micrometers (μm), in the light-emitting diode, and the photoresist layer 107 is removed, as shown in FIG. 1D.

Please refer to FIG. 1E, where a wet oxidation process is subsequently performed to form an oxide layer at a predetermined position in the epitaxial composite layer. In particular, one of the features of this invention is the introduction of water vapor containing oxygen through the sidewall of the mesa structure between the light-emitting layer 103 and the second compound semiconductor layer 104 into the interior of the light-emitting diode body, combined with a high-temperature heating process (e.g., 800° C. to 1100° C.) to promote the oxidation reaction. After approximately 1 hour, an oxide layer, such as an aluminum arsenide (AlAs) oxide layer, i.e., an aluminum oxide (Al₂O₃) layer, is formed. This oxide layer serves as a light-restricting layer 108 in the light-emitting diode structure, functioning as a current-blocking layer or an optical confinement layer. The light-restricting layer 108 has a light-restricting opening with an opening inner diameter D, which confines the light generated by the light-emitting layer 103 to pass through the light-restricting opening before being emitted externally. Due to the light-restricting opening of the light-restricting layer 108 restricting the current direction for confining and concentrating the light from the light-emitting layer, the light intensity and directionality of the conventional light-emitting diode are improved.

It should be noted that, in principle, a smaller opening inner diameter D forces the current to concentrate more toward the central region, thereby increasing the emission intensity. However, the opening inner diameter D should not be too small, as an excessively small light-restricting opening would lengthen the current path, causing an increase in the forward bias of the light-emitting diode, leading to power loss and increased thermal energy. On the other hand, the opening inner diameter D should not be too large, as an excessively large light-restricting opening would fail to effectively confine the light from the light-emitting layer, resulting in less-than-expected increases in light intensity. Specifically, the light-restricting opening has a minimum opening inner diameter having an inversely variable relationship with the emission wavelength band of the light-emitting layer 103. For example, when the emission wavelength band of the light-emitting layer varies from 620 nanometers (nm) to 940 nanometers (nm), the minimum opening inner diameter varies from 45 micrometers (μm) to 30 micrometers (μm). Additionally, the light-restricting opening has a maximum opening inner diameter of approximately 60 micrometers (μm). The detailed relationship between the emission wavelength band and the opening inner diameter D of the light-restricting layer 108 is shown in Table 1. For instance, in a light-emitting diode with an emission wavelength of 820 nanometers (nm), if the minimum opening inner diameter of the light-restricting opening is controlled to be approximately 40 micrometers (μm), the light-emitting diode of this invention can achieve over 100% higher emission intensity compared to a light-emitting diode without this light-restricting layer structure, thereby enhancing the emission efficiency of the point light source.

TABLE 1

| Emission Wavelength (nm) | Opening Inner Diameter D (μm) |
|---|---|
| 620 | 45 to 60 |
| 645 | 45 to 60 |
| 820 | 40 to 60 |
| 850 | 35 to 60 |
| 940 | 30 to 60 |

Next, please refer to FIG. 1F to FIG. 1K together, which illustrate schematic diagrams of manufacturing the emission window of the light-emitting diode, i.e., defining the outer diameter of the emission window of the light-emitting diode while simultaneously defining the size of the metal contact area. As shown in FIG. 1F, a silicon nitride layer 109 is deposited on the mesa structure as an insulating layer. Subsequently, a patterned passivation layer 110 is formed on the silicon nitride layer 109 to define the intended emission window of the light-emitting diode, as shown in FIG. 1G. Then, a portion of the silicon nitride layer 109 is etched away using the patterned passivation layer 110, and the passivation layer 110 is removed, as shown in FIG. 1H. Next, a vapor deposition process for the transparent conductive layer 111 is performed, allowing the transparent conductive material to fill the emission window and cover the surface of other areas of the mesa structure, as shown in FIG. 1I. The material of the transparent conductive layer 111 is selected from the group consisting of indium tin oxide (ITO), indium zinc oxide (IZO), zinc tin oxide (ZTO), aluminum-doped zinc oxide (AZO), gallium-doped zinc oxide (GZO), fluorine-doped tin oxide (FTO), and combinations thereof. It should be noted that another technical feature of the light-emitting diode of this invention is the use of a transparent conductive layer to cover the emission window area, reducing light reflection and absorption losses. Additionally, by controlling the thickness T of the transparent conductive layer 111 at the emission window, the forward bias of the light-emitting diode is improved. Specifically, the transparent conductive layer 111 has a minimum thickness having a positive variable relationship with the emission wavelength band of the light-emitting layer 103. For example, when the emission wavelength band of the light-emitting layer 103 varies from 620 nanometers (nm) to 940 nanometers (nm), the minimum thickness increases from 2400 angstroms (Å) to 4400 angstroms (Å). The detailed relationship between the emission wavelength band and the thickness T of the transparent conductive layer 111 is shown in Table 2. For instance, in a light-emitting diode with an emission wavelength of 820 nanometers (nm), if the minimum thickness of the transparent conductive layer is controlled to be 3000 angstroms (Å), the forward bias of the light-emitting diode can be reduced from the typical range of approximately 1.7˜1.8 V to approximately 1.6 V or even lower, thereby reducing power consumption and enhancing device performance.

TABLE 2

| | Thickness T (Å) of |
|---|---|
| Emission Wavelength (nm) | Transparent Conductive Layer |
| 620 | 2400 |
| 645 | 2600 |
| 820 | 3000 |
| 850 | 3600 |
| 940 | 4400 |

Please continue to refer to FIG. 1J, where a photoresist layer 112 is formed on the transparent conductive layer 111 to pattern and etch away portions of the transparent conductive layer 111 outside the photoresist layer 112, retaining the transparent conductive layer 111 on the mesa structure above the emission window. The photoresist layer 112 is then removed, as shown in FIG. 1K. Subsequently, a metal electrode process is performed to electrically connect the metal electrode to the transparent conductive layer 111, as shown in FIG. 1L to FIG. 1N. First, a patterned photoresist layer 113 is formed on the surface of the transparent conductive layer 111 on the mesa structure above the emission window, as shown in FIG. 1L. Next, a metal deposition process is performed to cover a P-type metal layer 114 in areas outside the photoresist layer 113, thereby electrically connecting the P-type metal layer 114 to the transparent conductive layer 111. By connecting the P-type electrode to the transparent conductive layer 111 of the emission window with metal, current conduction is facilitated, and electrical performance is improved. Additionally, the P-type metal layer 114 covering the sidewall of the mesa structure also prevents light leakage from the sides. After completing the metal deposition, the photoresist layer 113 is removed, as shown in FIG. 1M. Finally, as shown in FIG. 1N, a backside metal layer 115 is formed on the back side of the epitaxial growth substrate 100 to electrically connect to the first compound semiconductor layer 102 of the epitaxial composite layer, completing the final structure of the light-emitting diode in one embodiment of this invention.

As shown in FIG. 1N, the light-emitting diode of this invention utilizes a wet oxidation process to form a light-restricting layer on the light-emitting layer, concentrating the current and confining the light to pass through the light-restricting opening in the light-restricting layer before being emitted externally through the transparent conductive layer of the emission window. This enhances emission intensity and directionality, making the light-emitting diode of this invention more suitable for the technical requirements of high-end point light sources, enabling more precise and rapid subsequent digital signal processing applications. Additionally, by controlling the thickness of the transparent conductive layer in the emission window area, the forward bias can be further minimized, reducing power consumption and enhancing device performance.

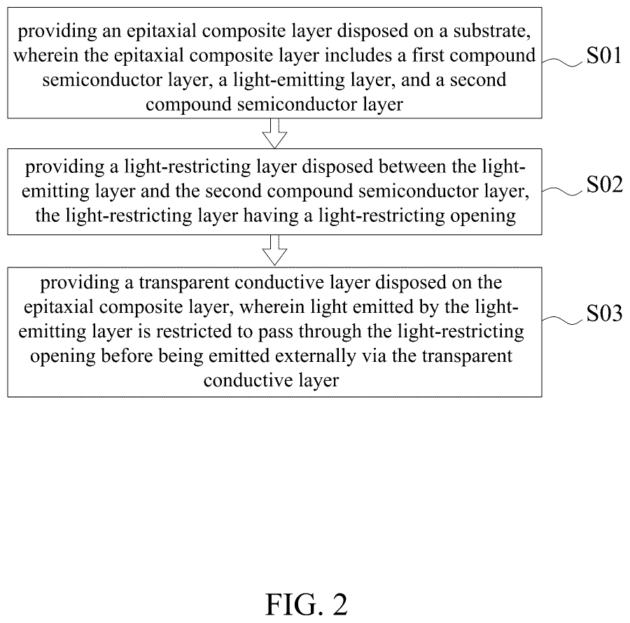

Please refer to FIG. 2, which illustrates a schematic flowchart of the manufacturing process for the light-emitting diode of this invention. First, in step S01, an epitaxial composite layer is provided on a substrate, wherein the epitaxial composite layer includes a first compound semiconductor layer, a light-emitting layer, and a second compound semiconductor layer, with the first compound semiconductor layer sandwiched between the substrate and the light-emitting layer. Next, in step S02, a light-restricting layer is provided between the light-emitting layer and the second compound semiconductor layer, wherein the light-restricting layer has a light-restricting opening. In step S03, a transparent conductive layer is provided on the epitaxial composite layer, wherein the light emitted by the light-emitting layer is restricted to pass through the light-restricting opening of the light-restricting layer before being emitted externally via the transparent conductive layer. The details of the components in the aforementioned process steps are described above and will not be repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A light-emitting diode, comprising:
a substrate;
an epitaxial composite layer including a first compound semiconductor layer, a light-emitting layer, and a second compound semiconductor layer, the first compound semiconductor layer being sandwiched between the substrate and the light-emitting layer;
a light-restricting layer disposed between the light-emitting layer and the second compound semiconductor layer, having a light-restricting opening; and
a transparent conductive layer disposed on the epitaxial composite layer,
wherein the light emitted by the light-emitting layer is restricted to pass through the light-restricting opening of the light-restricting layer before being emitted externally via the transparent conductive layer.

2. The light-emitting diode of claim 1, wherein the light-restricting opening has a minimum opening inner diameter, the minimum opening inner diameter having an inverse variable relationship with an emission wavelength band of the light-emitting layer.

3. The light-emitting diode of claim 2, wherein when the emission wavelength band of the light-emitting layer varies from 620 nanometers (nm) to 940 nanometers (nm), the minimum opening inner diameter varies from 45 micrometers (μm) to 30 micrometers (μm).

4. The light-emitting diode of claim 1, wherein the light-restricting opening has a maximum opening inner diameter of 60 micrometers (μm).

5. The light-emitting diode of claim 1, wherein the light-restricting layer is an oxide layer.

6. The light-emitting diode of claim 1, wherein the transparent conductive layer has a minimum thickness, the minimum thickness having a positive variable relationship with an emission wavelength band of the light-emitting layer.

7. The light-emitting diode of claim 6, wherein when the emission wavelength band of the light-emitting layer varies from 620 nanometers (nm) to 940 nanometers (nm), the minimum thickness varies from 2400 angstroms (Å) to 4400 angstroms (Å).

8. The light-emitting diode of claim 1, wherein the material of the transparent conductive layer is selected from the group consisting of indium tin oxide (ITO), indium zinc oxide (IZO), zinc tin oxide (ZTO), aluminum-doped zinc oxide (AZO), gallium-doped zinc oxide (GZO), fluorine-doped tin oxide (FTO), and combinations thereof.

9. The light-emitting diode of claim 1, wherein the first compound semiconductor layer is a first conductivity-type aluminum gallium arsenide (AlGaAs) layer, and the second compound semiconductor layer is a second conductivity-type aluminum gallium arsenide layer.

10. The light-emitting diode of claim 9, further comprising a gallium phosphide (GaP) layer sandwiched between the second conductivity-type aluminum gallium arsenide layer and the transparent conductive layer, and forming an ohmic contact with the transparent conductive layer.

11. The light-emitting diode of claim 1, further comprising a reflective layer disposed between the substrate and the first compound semiconductor layer to reflect the light emitted by the light-emitting layer through the light-restricting opening of the light-restricting layer before being emitted externally via the transparent conductive layer.

12. The light-emitting diode of claim 11, wherein the reflective layer is a distributed Bragg reflector (DBR).

13. A manufacturing method of a light-emitting diode, comprising:
providing an epitaxial composite layer disposed on a substrate, wherein the epitaxial composite layer includes a first compound semiconductor layer, a light-emitting layer, and a second compound semiconductor layer, the first compound semiconductor layer being sandwiched between the substrate and the light-emitting layer;
providing a light-restricting layer disposed between the light-emitting layer and the second compound semiconductor layer, the light-restricting layer having a light-restricting opening; and
providing a transparent conductive layer disposed on the epitaxial composite layer,
wherein the light emitted by the light-emitting layer is restricted to pass through the light-restricting opening of the light-restricting layer before being emitted externally via the transparent conductive layer.

14. The manufacturing method of the light-emitting diode of claim 13, wherein the step of providing a light-restricting layer is a step of providing a light-restricting layer with a light-restricting opening having a minimum opening inner diameter, the minimum opening inner diameter having an inverse variable relationship with the emission wavelength band of the light-emitting layer, and when the emission wavelength band of the light-emitting layer varies from 620 nanometers (nm) to 940 nanometers (nm), the minimum opening inner diameter varies from 45 micrometers (μm) to 30 micrometers (μm).

15. The manufacturing method of the light-emitting diode of claim 13, wherein the step of providing a light-restricting layer is a step of providing a light-restricting layer with a light-restricting opening having a maximum opening inner diameter of 60 micrometers (μm).

16. The manufacturing method of the light-emitting diode of claim 13, further comprising a mesa etching process to etch and remove a portion of the epitaxial composite layer, exposing a sidewall of the epitaxial composite layer.

17. The manufacturing method of the light-emitting diode of claim 16, wherein the step of providing a light-restricting layer is a step of performing a wet oxidation process, allowing oxygen and water to enter the epitaxial composite layer through the exposed sidewall of the epitaxial composite layer to form an oxide layer between the light-emitting layer and the second compound semiconductor layer.

18. The manufacturing method of the light-emitting diode of claim 13, wherein the step of providing a transparent conductive layer comprises providing a transparent conductive layer with a minimum thickness, the minimum thickness having a positive variable relationship with the emission wavelength band of the light-emitting layer, and when the emission wavelength band of the light-emitting layer varies from 620 nanometers (nm) to 940 nanometers (nm), the minimum thickness varies from 2400 angstroms (Å) to 4400 angstroms (Å).

19. The manufacturing method of the light-emitting diode of claim 13, wherein the material of the transparent conductive layer is selected from the group consisting of indium tin oxide (ITO), indium zinc oxide (IZO), zinc tin oxide (ZTO), aluminum-doped zinc oxide (AZO), gallium-doped zinc oxide (GZO), fluorine-doped tin oxide (FTO), and combinations thereof.

20. The manufacturing method of the light-emitting diode of claim 13, wherein the first compound semiconductor layer is a first conductivity-type aluminum gallium arsenide (AlGaAs) layer, and the second compound semiconductor layer is a second conductivity-type aluminum gallium arsenide layer.

21. The manufacturing method of the light-emitting diode of claim 20, further comprising a step of providing a gallium phosphide (GaP) layer, being sandwiched between the second conductivity-type aluminum gallium arsenide layer and the transparent conductive layer, and forming an ohmic contact with the transparent conductive layer.

22. The manufacturing method of the light-emitting diode of claim 13, further comprising a step of providing a reflective layer disposed between the substrate and the first compound semiconductor layer to reflect the light emitted by the light-emitting layer through the light-restricting opening of the light-restricting layer before being emitted externally via the transparent conductive layer.
